(19) United States
(12) Patent Application Publication
(10) Pub. No.: US 2026/0129827 A1
(43) Pub. Date: May 7, 2026

(54) WORD LINE CONTACT FOR 3D MEMORY

(71) Applicant: Applied Materials, Inc., Santa Clara, CA (US)

(72) Inventors: Chang Seok Kang, Santa Clara, CA (US); Tomohiko Kitajima, San Jose, CA (US); Raghuveer Satya Makala, Campbell, CA (US)

(73) Assignee: Applied Materials, Inc., Santa Clara, CA (US)

(21) Appl. No.: 19/372,584

(22) Filed: Oct. 29, 2025

Related U.S. Application Data
(60) Provisional application No. 63/716,789, filed on Nov. 6, 2024.

(51) Int. Cl. H10B 12/00

(52) U.S. Cl. CPC H10B 12/30; H10B 12/03; H10B 12/05

(57) ABSTRACT

Described are memory devices having an array region and a contact region adjacent the array region. The array region includes a cell transistor and a cell capacitor. The contact region includes a plurality of word line contacts extending in a first direction and a second plurality of word line contacts extending in a second direction. The memory stack comprises a plurality of conductor layers and a corresponding plurality of dielectric layers alternatingly arranged in a plurality of stacked pairs. Methods of forming a memory device are described.

### CROSS-REFERENCE TO RELATED APPLICATIONS

This application claims priority to U.S. Provisional Application No. 63/716,789, filed Nov. 6, 2024, the entire disclosure of which is hereby incorporated by reference herein.

### TECHNICAL FIELD

Embodiments of the present disclosure pertain to the field of electronic devices and electronic device manufacturing. More particularly, embodiments of the disclosure provide a three-dimensional (3D) dynamic random-access memory cell.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bit line, the word line, and the reference voltage. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive word lines through the cell, the size of the cell capacitor, and the compatibility of array devices with nonarray devices. The formation of a low resistance contact between the active area and the 3D DRAM bottom electrode is essential for performance of the device.

DRAM is composed of hundreds of sub-blocks. For each sub-block, word lines (WL) and bit lines (BL) are connected with controlling circuits. Multiple cells are stacked in a 3D DRAM. Every word line of each stack should have a contact to connect the word line with controlling circuits in a sub-array. The same number of contacts are necessary as the number of word lines (WL) stacked. Word line contact (WLC) area, therefore, occupies a significant portion of total chip area. The reduction in word line contact (WLC) area is critical to decrease chip area.

There is a need in the art, therefore, for memory devices and methods of forming memory devices that have a reduced chip area.

### SUMMARY

One or more embodiments of the disclosure are directed to a memory device. In one or more embodiments, a memory device comprises: a plurality of stacked word lines coupled to a plurality of stacked memory cells, the plurality of stacked word lines comprising a first word line and a second word line; a first word line contact in contact with the first word line and extending in a first direction from the first word line; and a second word line contact in contact with the second word line and extending in a second direction from the second word line, wherein the second direction is opposite to the first direction.

One or more embodiments of the disclosure are directed to a memory device. In one or more embodiments, a memory device comprises: a memory stack comprising a plurality of conductor layers and semiconductor layers and a corresponding plurality of dielectric layers alternatingly arranged in a plurality of stacked pairs, the memory stack having a first direction and a second direction; at least two first contact regions extending in the first direction; and at least two second contact regions extending in the second direction.

Additional embodiments of the disclosure are directed to a memory device. In one or more embodiments, a memory device comprises: an array region on a substrate, the array region including a cell transistor and a cell capacitor; and a contact region having a first direction and a second direction adjacent the array region on the substrate, the contact region comprising a plurality of conductor layers and semiconductor layers and a corresponding plurality of dielectric layers alternatingly arranged in a plurality of stacked pairs, at least two first contact regions extending in the first direction, and at least two second contact regions extending in the second direction.

Further embodiments of the disclosure are directed to methods of forming a memory device. In one or more embodiments, a method of forming a memory device comprises: forming a memory stack on a substrate, the memory stack comprising a plurality of conductor layers and semiconductor layers and a corresponding plurality of dielectric layers alternatingly arranged in a plurality of stacked pairs, the memory stack having a first direction and a second direction; patterning the memory stack in the first direction to form a plurality of first contact openings extending in the first direction; patterning the memory stack in the second direction to form a plurality of second contact openings extending in the second direction; and depositing a conductive material in each of the plurality of first contact openings and in the plurality of second contact openings to form a plurality of first contacts and a plurality of second contacts, the plurality of first contacts extending along the first direction and the plurality of second contacts extending along the second direction.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments described herein are illustrated by way of example and not limited in the figures of the accompanying drawings in which like reference numbers indicate similar elements.

FIG. 1 illustrates a process flow diagram of a method according to one or more embodiments;

FIG. 2 illustrates a cross-sectional schematic of a memory device according to the prior art;

FIG. 3 illustrates a cross-sectional schematics of a memory device according to one or more embodiments of the disclosure;

FIG. 4 is a cross-sectional schematic of a memory device according to one or more embodiments of the disclosure;

FIG. 4A to 4Z′ illustrate cross-sectional views taken along line A-B of FIG. 4 of the array region of a memory device according to one or more embodiments of the disclosure;

FIG. 5A to 5N illustrate cross-sectional views taken along line C-D of FIG. 4 of the contact region of a memory device according to one or more embodiments of the disclosure;

FIGS. 6A to 6D illustrate cross-sectional views of a memory device according to one or more embodiments of the disclosure; and

FIG. 7 illustrates a cluster tool according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

As used in this specification and the appended claims, the terms “precursor”, “reactant”, “reactive gas” and the like are used interchangeably to refer to any gaseous species that can react with the substrate surface.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A, e.g., aluminum precursor) is pulsed into the reaction zone followed by a first time delay. Next, a second precursor or compound B (e.g., oxidant) is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneously or substantially simultaneously. As used herein, “substantially simultaneously” refers to either co-flow or where there is overlap for a majority of exposures of the precursors.

Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that has been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells.

Traditionally, DRAM cells have recessed high work-function metal structures in buried word line structure. In a DRAM device, a bit line is formed in a metal level situated above the substrate, while the word line is formed at the polysilicon gate level at the surface of the substrate. In the buried word line (bWL), a word line is buried below the surface of a semiconductor substrate using a metal as a gate electrode.

The embodiments of the disclosure are described by way of the Figures, which illustrate devices (e.g., 3D DRAM) and processes for forming devices in accordance with one or more embodiments of the disclosure. The processes shown are merely illustrative possible uses for the disclosed processes, and the skilled artisan will recognize that the disclosed processes are not limited to the illustrated applications.

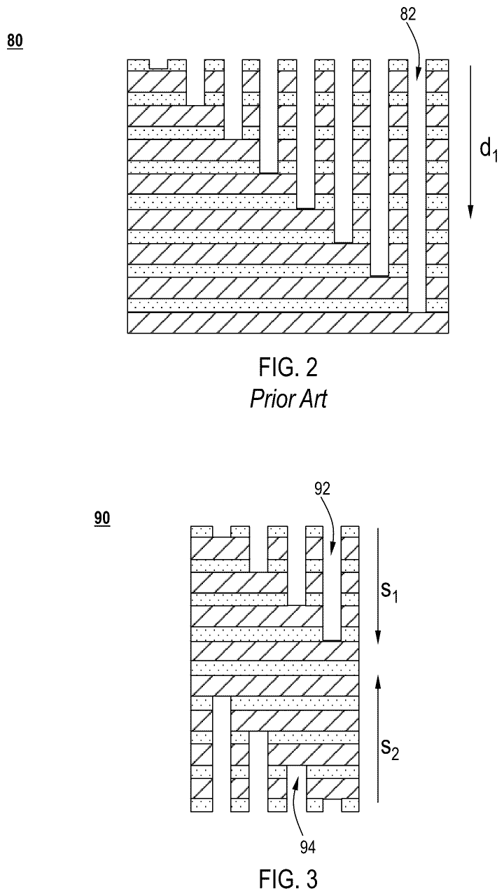

In current 3D DRAM devices, as illustrated in FIG. 2 which is a device 80 according to the prior art, multiple word lines 82 are arranged in the bitline direction, di. Each word line should be separated from the other and have a separate word line contact. The word line contact pitch is typically 100 nm to 500 nm, where the deeper the contacts, the greater the word line pitch. In order to achieve a cost effective chip area, however, a decrease in the area and depth of the word line contact is desired.

As illustrated in FIG. 3, in one or more embodiments, memory devices 90 are provided which advantageously place word line contacts 92,94 on both the top side, s1, and bottom side, s2, so that the same number of word line contacts are formed in a reduced word line contact area. In one or more embodiments, the size of the word line contact area is advantageously reduced by greater than fifty percent (>50%). Additionally, one or more embodiments provide a reduction in the depth critical dimension (CD) necessary to form the word line contact. In one or more embodiments, the depth of the word line contact opening is advantageously reduced by greater than fifty percent (>50%).

Although the disclosure will routinely identify specific 3D DRAM devices, and components thereof, it will be readily understood that the device and methods are equally applicable to other memory devices, orientations thereof, as processes for forming such devices. Accordingly, the technology should not be considered to be so limited as for use with these specific devices or methods alone. The disclosure will discuss one possible semiconductor device that may include one or more components, utilizing word line contacts formed on both the top side and bottom side, so that the same number of word line contacts are formed in a reduced word line contact area according to embodiments of the present technology before additional variations and adjustments to this apparatus according to embodiments of the present technology are described.

In one or more embodiments, metal deposition and other processes can be carried out in an isolated environment (e.g., a cluster process tool). Accordingly, some embodiments of the disclosure provide integrated tool systems with related process modules to implement the methods.

One or more embodiments advantageously provide a plurality of stacked word lines coupled to a plurality of stacked memory cells. The plurality of stacked word lines includes a first word line and a second word line. A first word line contact is in contact with the first word line and extends in a first direction from the first word line. A second word line contact is in contact with the second word line and extends in a second direction from the second word line. The second direction is opposite to the first direction. In some embodiments, the plurality of stacked word lines includes a third word line and a fourth word line. The memory device includes a third word line contact contacting the third word line and extending in the first direction from the third word line, and a fourth word line contact contacting the fourth word line and extending in the second direction from the fourth word line. In some embodiments, the first word line contact has a height or depth that is greater than the height or depth of the third word line contact, and the second word line contact has a height or depth that is greater than the height or depth of the fourth word line contact.

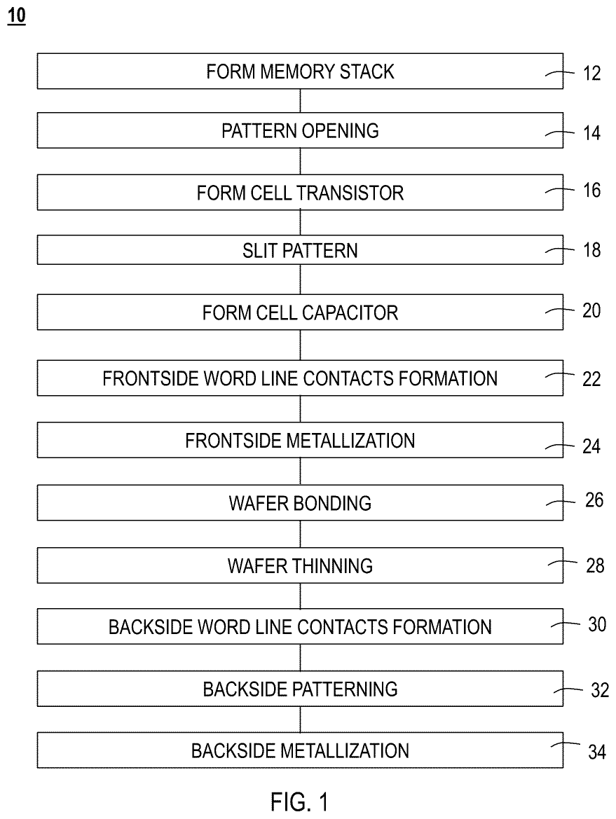

FIG. 1 illustrates a process flow diagram for a method 10 that can include any or all of the processes illustrated. Additionally, the order of the individual processes can be varied for some portions. The method 10 can start at any of the enumerated processes without deviating from the disclosure. With reference to FIG. 1, at operation 12, a memory stack is formed. At operation 14, an opening is patterned into the memory stack. At operation 16, the cell transistor is formed. At operation 18, the memory stack is slit patterned. At operation 20, the cell capacitor is formed. At operation 22, word line contacts are formed on the frontside of the device. At operation 24, the frontside metallization is formed. At operation 26, the device is bonded to a wafer. At operation 28, the wafer is thinned. At operation 30, the word line contacts are formed on the backside of the device. At operation 32, the backside is patterned. At operation 34, the backside metallization is formed.

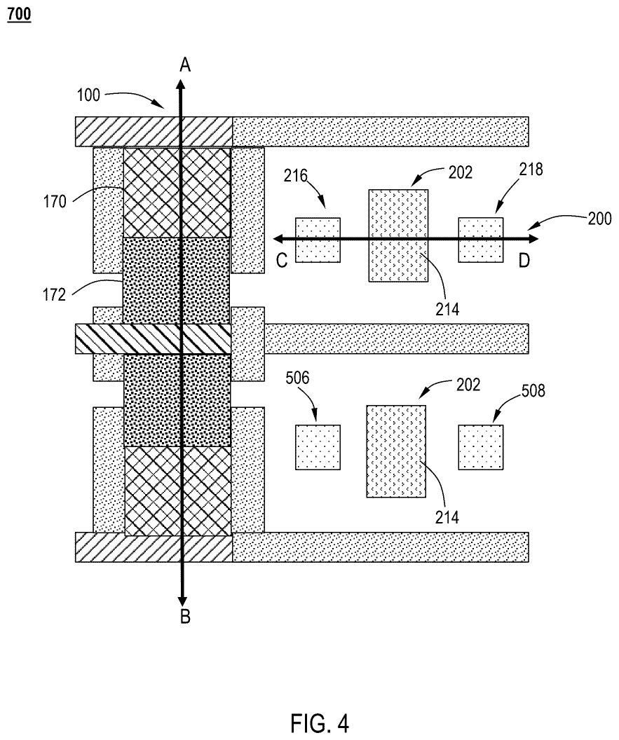

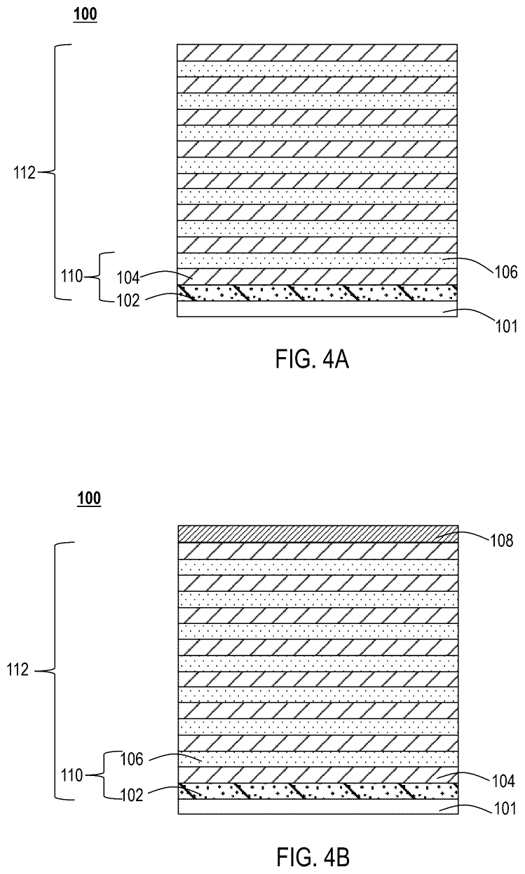

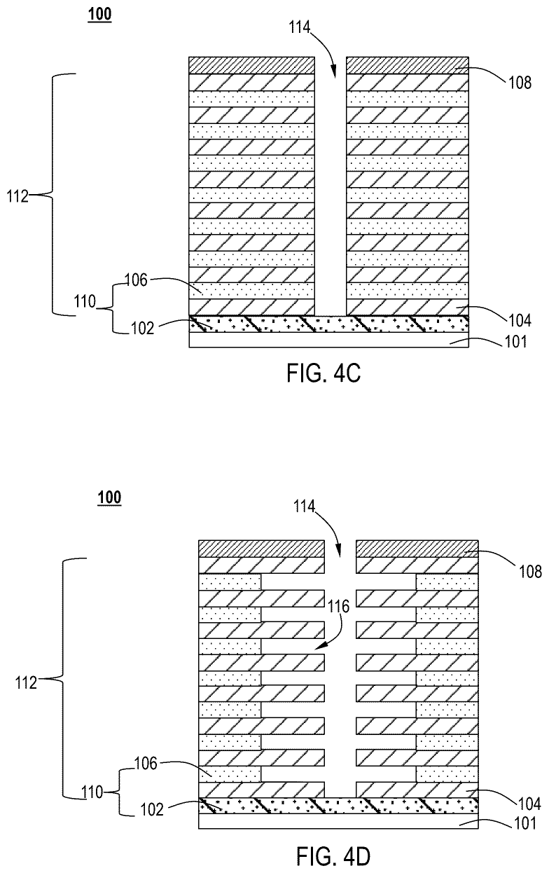

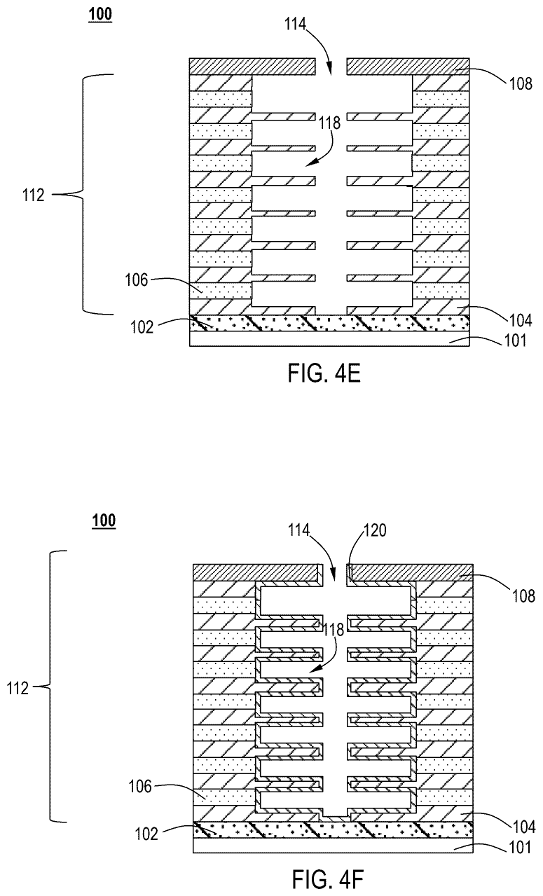

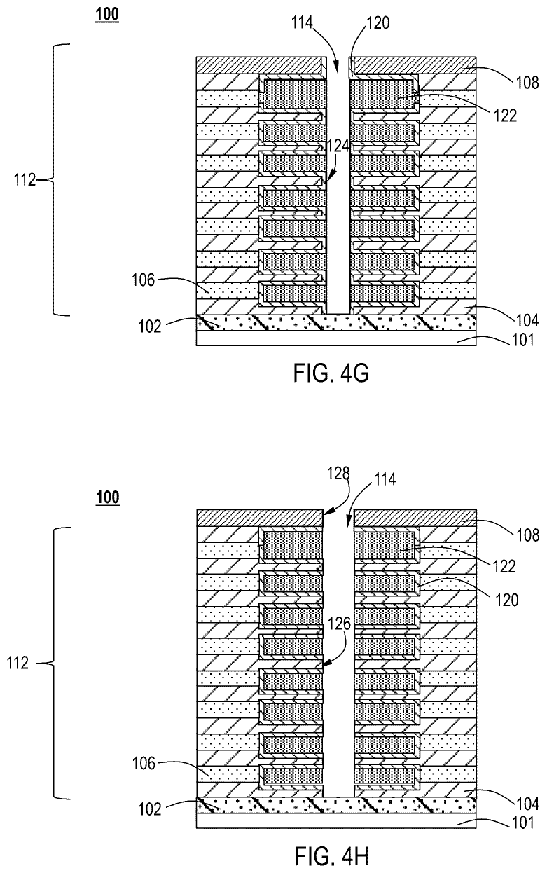

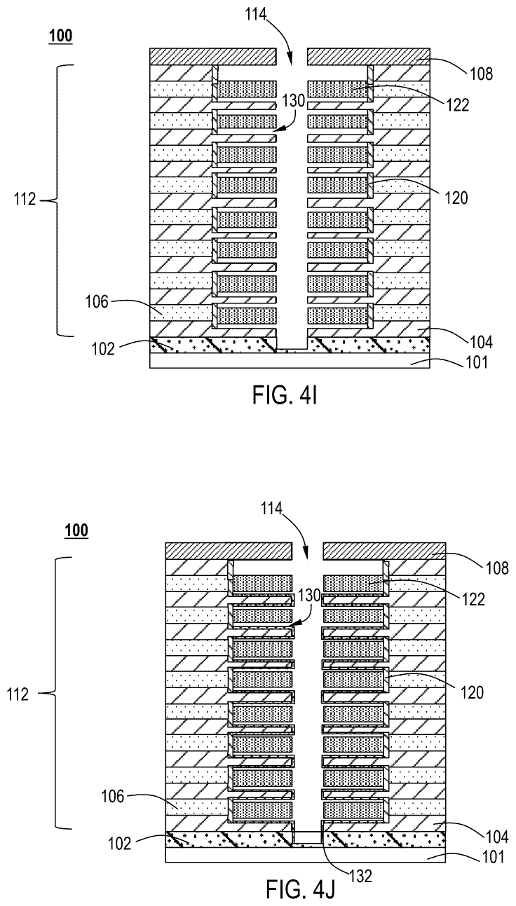

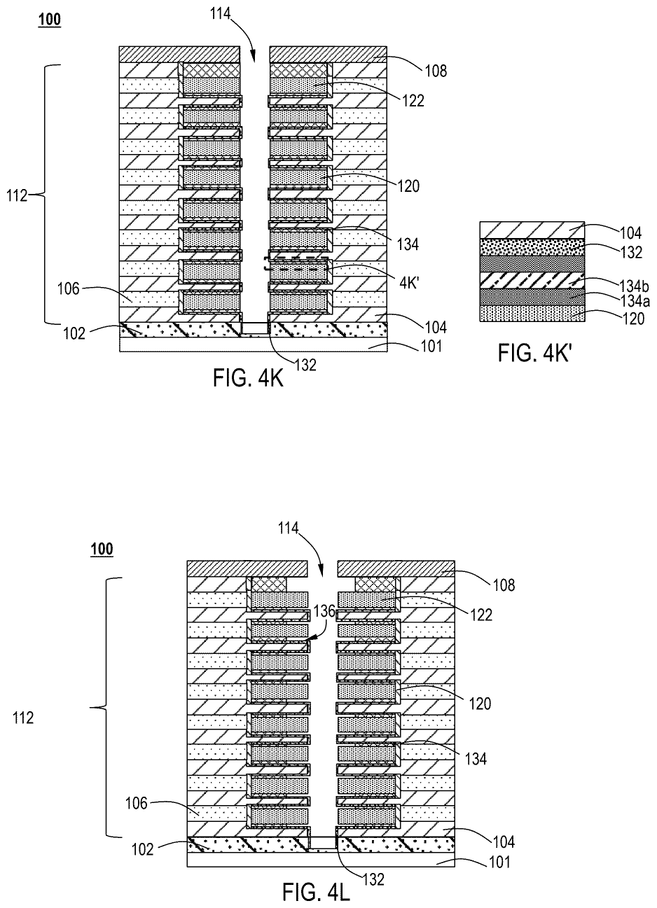

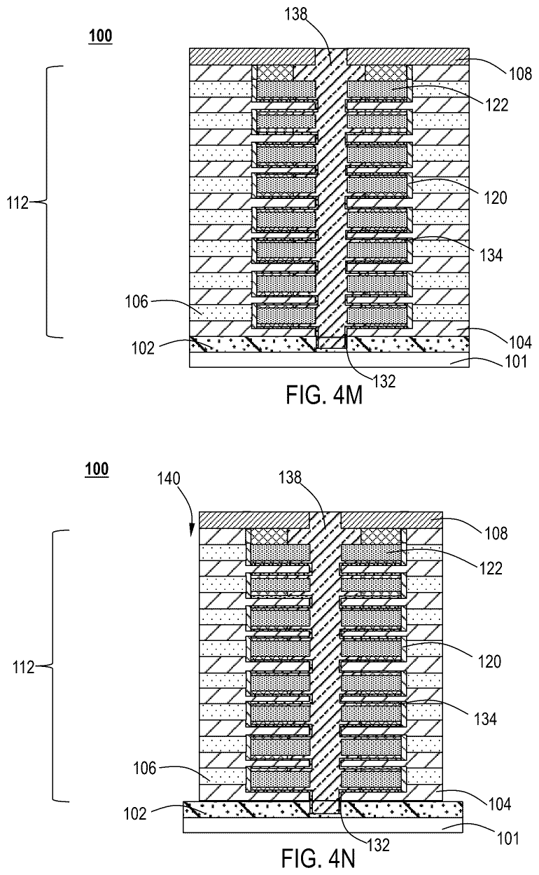

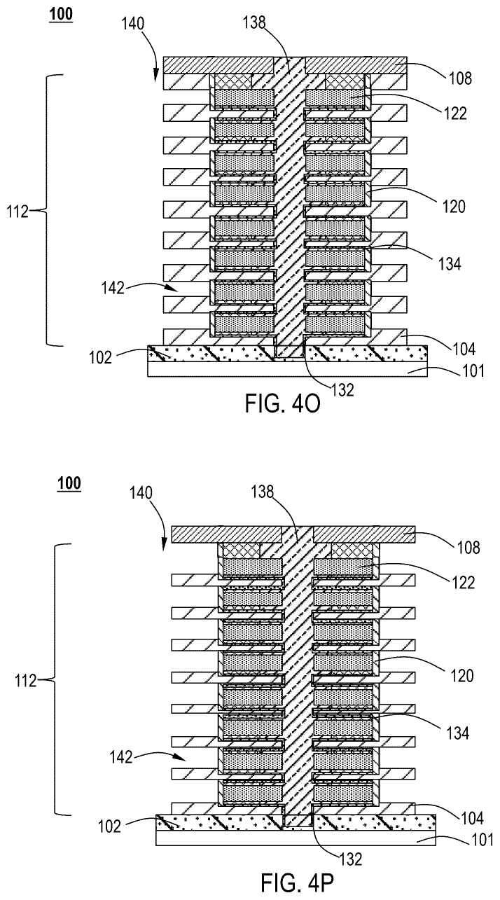

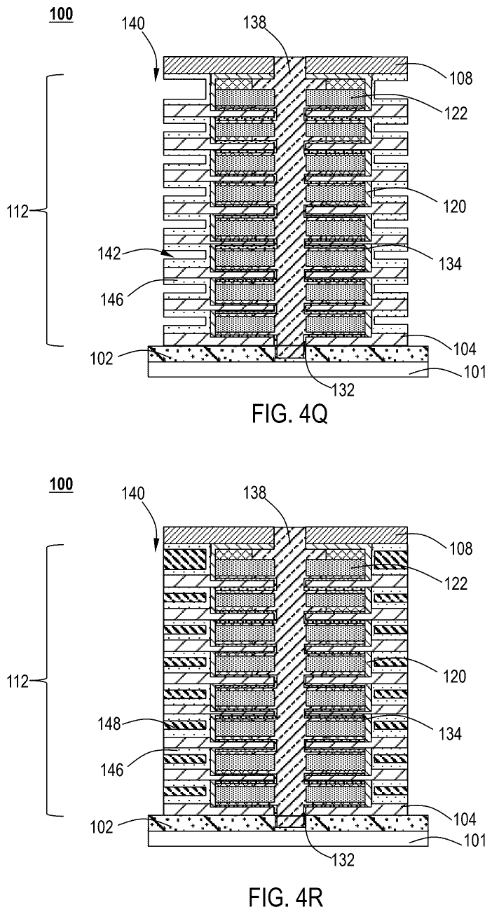

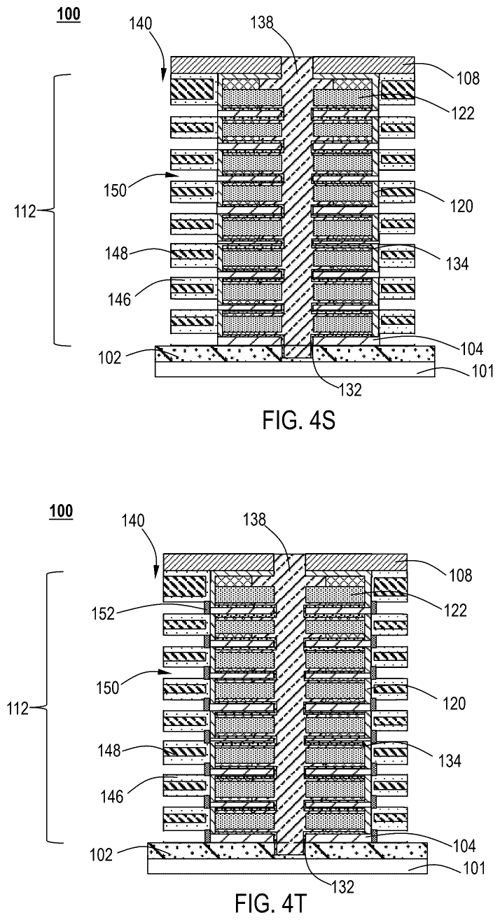

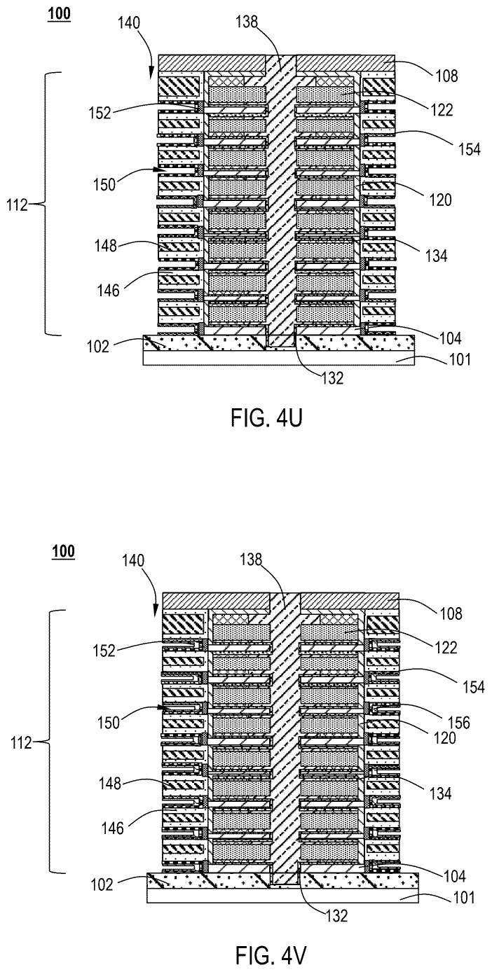

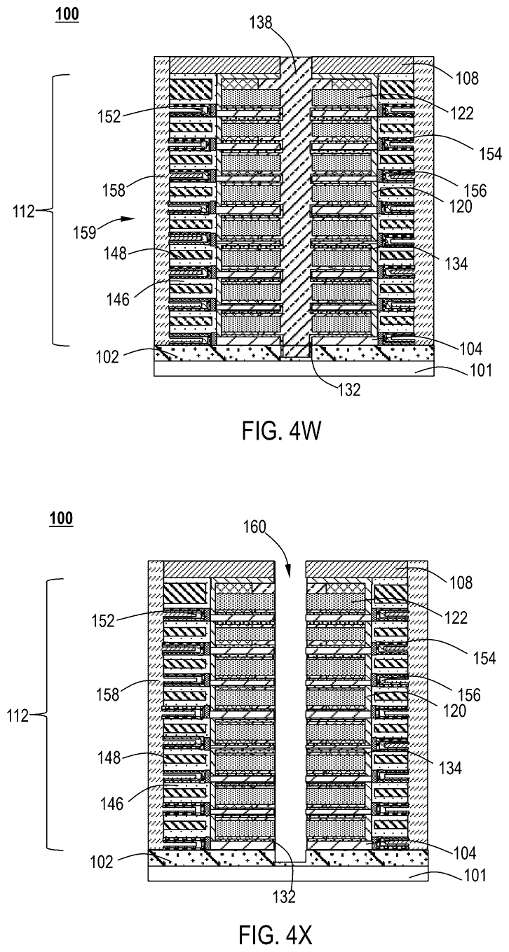

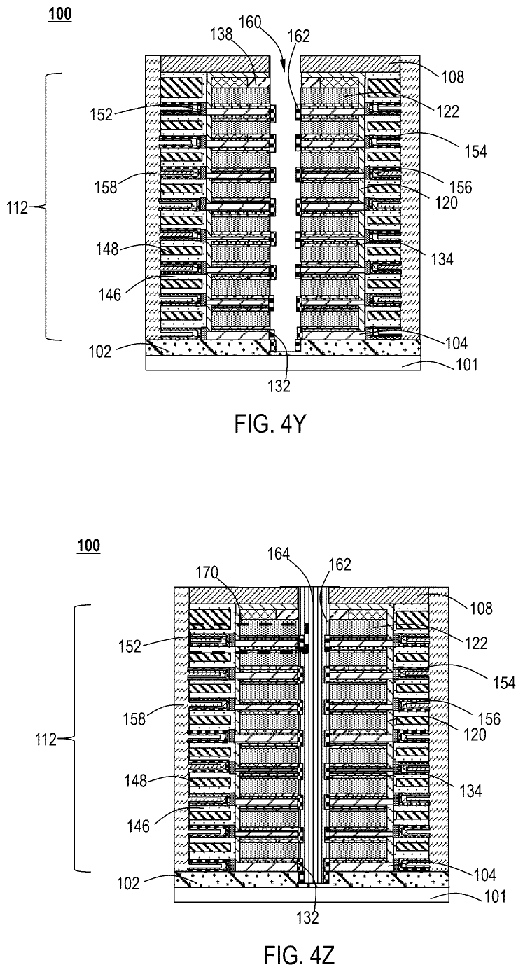

FIG. 4 is a cross-sectional schematic of a memory device 700 according to one or more embodiments of the disclosure. FIG. 4 illustrates the cell capacitor 170 and the cell transistor 172 in the array region 100 of the memory device 700. The word line contacts 216,218,506,508 and the slit pattern opening 202 (filled with an oxide material 214) are visible in the word line contact region 200.

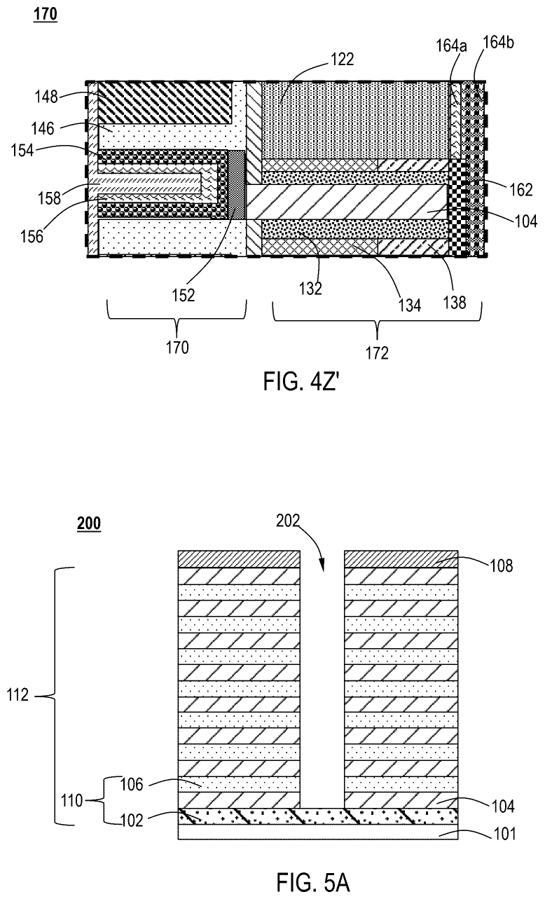

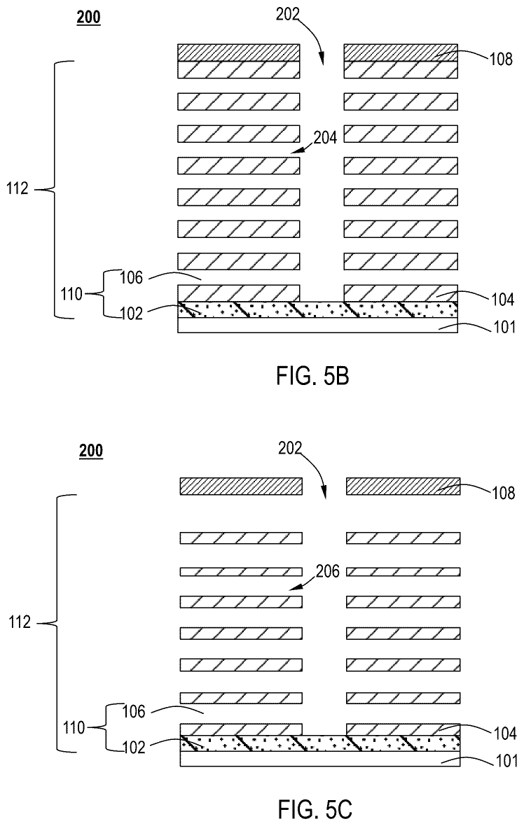

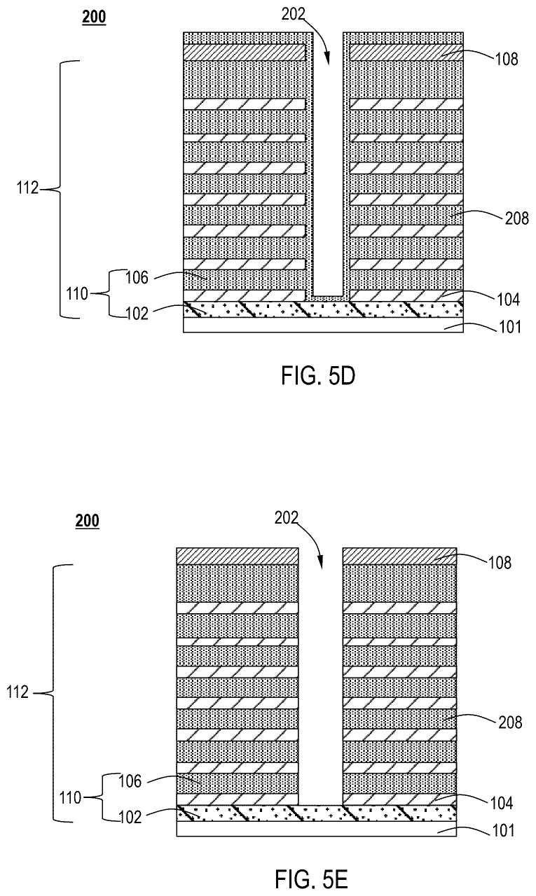

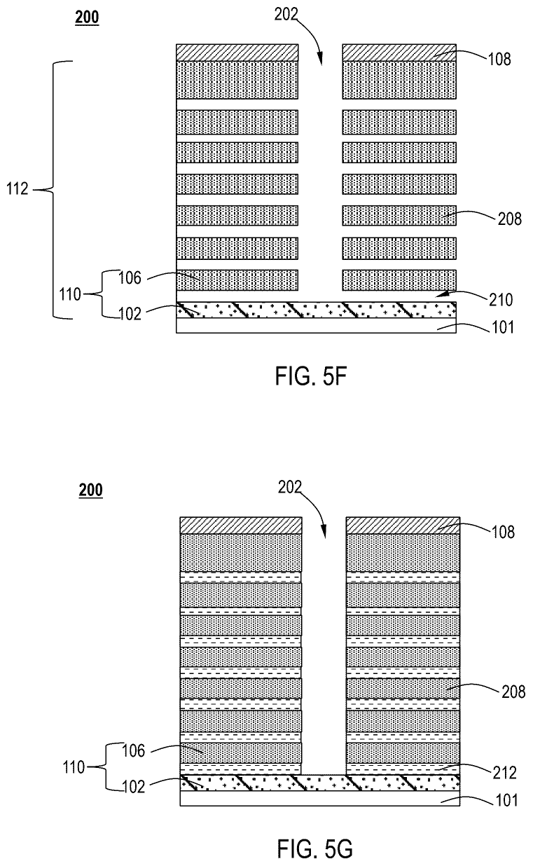

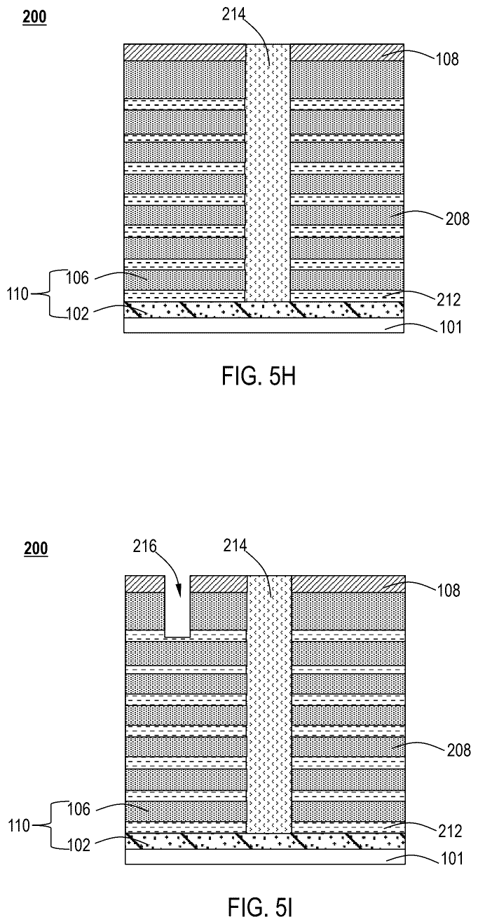

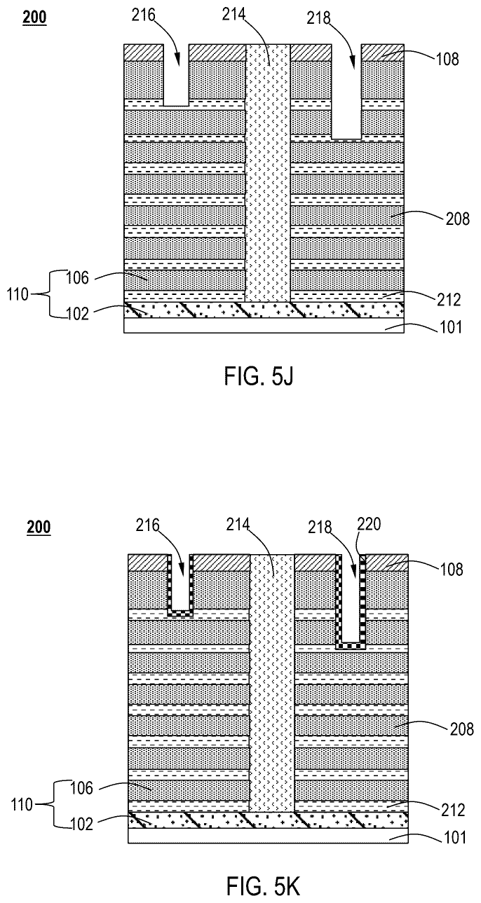

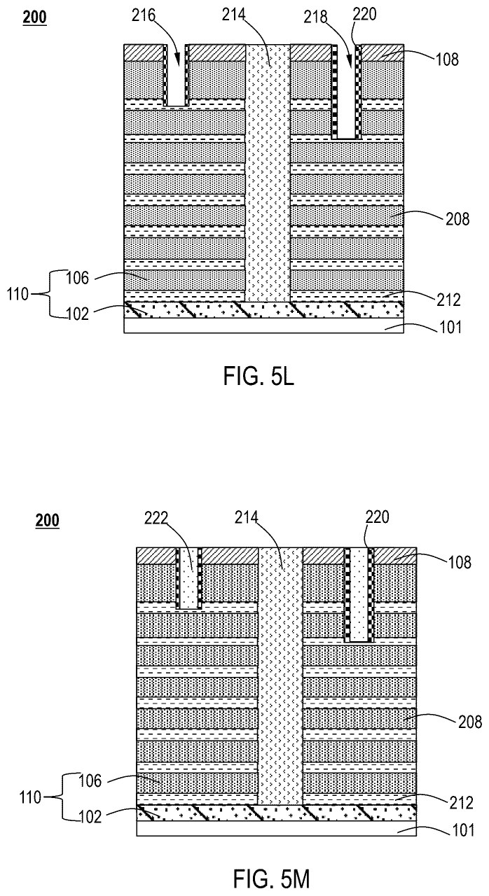

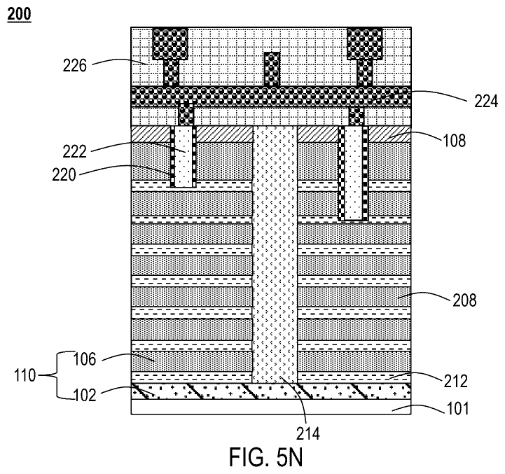

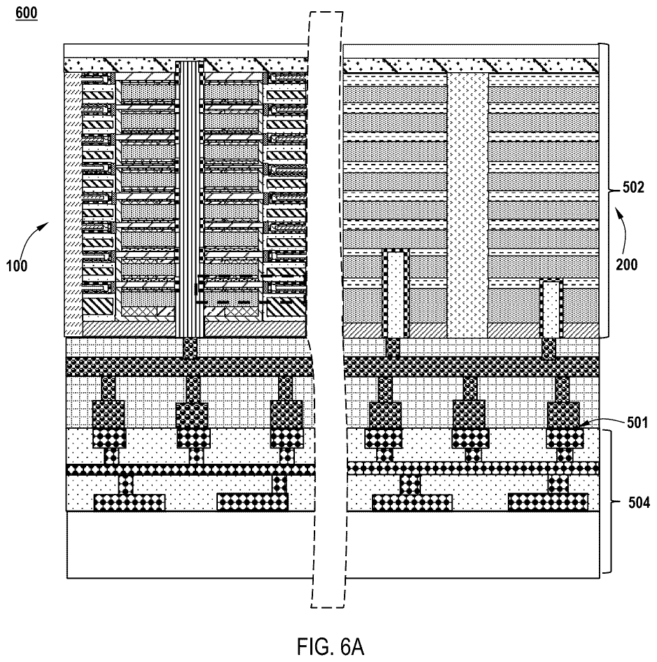

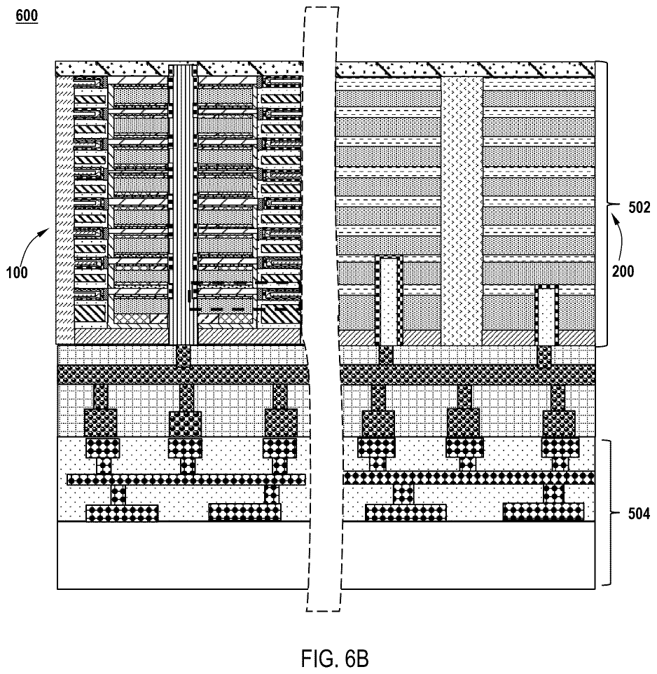

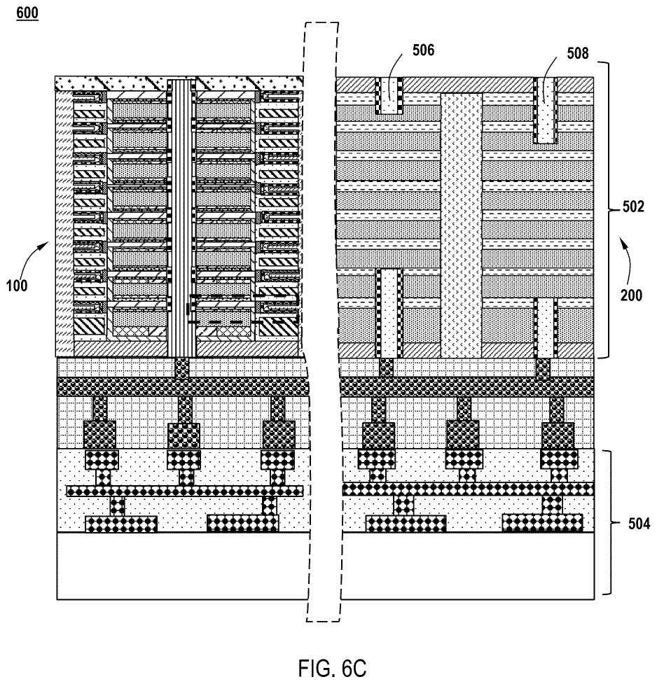

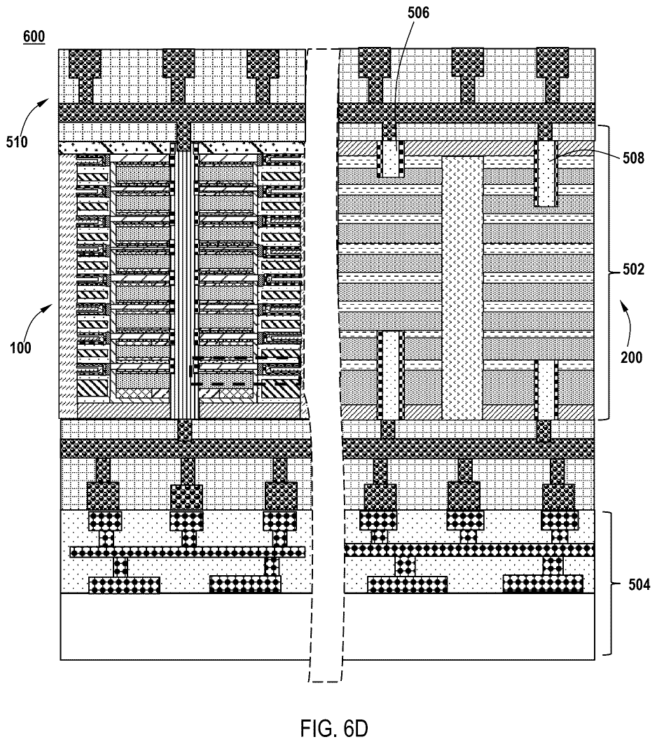

FIGS. 4A through 4Z′ illustrate cross-sectional views 100 along line A-B of FIG. 4, which is an array region 100 of a memory device during frontside processing according to the method of one or more embodiments. FIGS. 5A through 5N illustrate cross-sectional views 200 along line C-D of FIG. 4, which is a contact region 200 of a memory device during backside processing according to the method of one or more embodiments. FIGS. 6A to 6D illustrate a memory device 600 including an array region 100 and a contact region 200 on a wafer.

With reference to FIG. 1 and FIG. 4A, at operation 12, an initial or starting mold is formed in accordance with one or more embodiments of the disclosure. In some embodiments, the array region 100 shown in FIG. 4A is formed on a bare substrate (not illustrated) in layers. In one or more embodiments, the array region of FIG. 4A is made up of a substrate 101 and a unit stack 110. In one or more embodiments, the unit stack 110 includes an insulating layer 102, at least one sacrificial layer 104, and a semiconductor layer 104. In some embodiments, the unit stack 110 includes an insulating layer 102, a first sacrificial layer 104 on the insulating layer 102, a semiconductor layer 104 on the first sacrificial layer 104. Repeating unit stacks 110 stacked vertically on top of one another form a memory stack 112 on the substrate. The memory stack 112 includes alternating layers of the sacrificial layer 104 and the semiconductor layer 108.

The substrate 101 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

In one or more embodiments, an insulating layer 102 is on a top surface of the substrate 101. The insulating layer 102 can be formed by any suitable technique known to the skilled artisan and can be made from any suitable material. In one or more embodiments, the insulating layer 102 comprises silicon oxide (SiOₓ).

In one or more embodiments, a semiconductor layer 104 may be formed on the insulating layer 102. The semiconductor layer 104 may also be referred to as the active layer or the memory layer.

As used herein, the term “active” or “memory layer” refers to a layer of material in which a channel, a bit line, a word line, or a capacitor can be made. In one or more embodiments, the active layer, or the semiconductor layer 104 comprises one or more of silicon or doped silicon. In some embodiments, the semiconductor layer 104 may comprise a semiconductor material that is a doped material, such as n-doped silicon (n-Si), or p-doped silicon (p-Si). In some embodiments, the semiconductor layer 104 may be doped using any suitable process such as an ion implantation process. As used herein, the term “n-type” refers to a semiconductor layer 104 that is created by doping with an electron donor element during manufacture. The term n-type comes from the negative charge of the electron. In n-type semiconductor material layers, electrons are the majority carriers and holes are the minority carriers. As used herein, the term “p-type” refers to the positive charge of a well (or hole). As opposed to n-type semiconductor materials, p-type semiconductor materials have a larger hole concentration than electron concentration. In p-type semiconductor materials, holes are the majority carriers and electrons are the minority carriers. In one or more embodiments, the dopant is selected from one or more of boron (B), gallium (Ga), phosphorus (P), arsenic (As), other semiconductor dopants, or combinations thereof. In some embodiments, the semiconductor layer 104 comprises several different conductive or semiconductor materials.

In one or more embodiments, a sacrificial layer 106 is on the semiconductor layer 104. The sacrificial layer 106 may comprise any suitable material known to the skilled artisan. In one or more embodiments, the sacrificial layer 106 comprises silicon germanium (SiGe).

The sacrificial layer 106 and the insulating layer 102 may be formed on a substrate 101 and can be made of any suitable material. In some embodiments, one or more of the sacrificial layer 106 and the insulating layer 102 may be removed and replaced in later processes. In some embodiments, one or more of the sacrificial layer 106 and the insulating layer 102 are not removed and remain within the array region 100. In this case, the term “sacrificial” has an expanded meaning to include permanent layers and may be referred to as the conductive layer. In one or more embodiments, one or more of the sacrificial layer 106 and the insulating layer 102 comprise a material that can be removed selectively versus the layers of the neighboring memory stack.

The memory stack 112 in the illustrated embodiment comprises a plurality of alternating sacrificial layers 106 and a corresponding plurality of semiconductor layers 104. While the memory stack 112, illustrated in FIG. 4A, has seven sets of alternating sacrificial layers 106 and semiconductor layers 104, one of skill in the art recognizes that this is merely for illustrative purposes only. The memory stack 112 may have any number of alternating sacrificial layers 106 and semiconductor layers 104. For example, in some embodiments, the memory stack 112 comprises 192 pairs of alternating sacrificial layers 106 and semiconductor layers 104. In other embodiments, the memory stack 112 comprises greater than 50 pairs of alternating sacrificial layers 106 and semiconductor layers 104, or greater than 100 pairs of alternating sacrificial layers 106 and semiconductor layers 104, or greater than 300 pairs of alternating sacrificial layers 106 and semiconductor layers 104.

In one or more embodiments, sequential depositions are used to form many active area regions. In one or more embodiments, alternating layers of films, e.g., oxide-polysilicon, polysilicon-nitride, oxide-nitride, silicon-silicon germanium, oxide-nitride-silicon-nitride, are deposited.

In one or more embodiments, the sacrificial layers 106 independently comprise an insulating material. In one or more embodiments, the sacrificial layers 106 comprises silicon germanium (SiGe), and the insulating layer 102 comprises an oxide material, e.g., silicon oxide. The sacrificial layers 106 comprise a material that is etch selective relative to the insulating layer 102 and the semiconductor layers 104 so that the sacrificial layers 106 can be removed without substantially affecting the insulating layer 102 and the semiconductor layers 104. In one or more embodiments, the sacrificial layers 106 comprise, consist essentially of, or consist of silicon germanium (SiGe). In one or more embodiments, the insulating layer 102 comprises, consists essentially of, or consists of silicon oxide (SiOₓ). In one or more embodiments the sacrificial layers 106, the insulating layer 102, and the semiconductor layers 104 are deposited by chemical vapor deposition (CVD) or physical vapor deposition (PVD).

The individual alternating layers may be formed to any suitable thickness. In one or more embodiments, each sacrificial layer 106 has a sacrificial layer thickness. In some embodiments, the thickness of each sacrificial layer 106 is approximately equal. As used in this regard, thicknesses which are approximately equal are within +/−5% of each other. The thickness of the semiconductor layers 104 may be relatively thick as compared to the thickness of the sacrificial layers 106 and the insulating layer 102.

In one or more embodiments, the insulating layer 102 has a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments the insulating layer 102 has a thickness in the range of from about 0.5 to about 40 nm.

In one or more embodiments, the sacrificial layers 106 have a thickness in a range of from about 0.5 nm to about 50 nm, including about 1 nm, about 3 nm, about 5 nm, about 7 nm, about 10 nm, about 12 nm, about 15 nm, about 17 nm, about 20 nm, about 22 nm, about 25 nm, about 27 nm, about 30 nm, about 32 nm, about 35 nm, about 37 nm, about 40 nm, about 42 nm, about 45 nm, about 47 nm, and about 50 nm. In one or more embodiments, the sacrificial layer 106 has a thickness in the range of from about 5 to about 50 nm.

In one or more embodiments, the semiconductor layers 104 have a thickness in a range of from about 30 nm to about 150 nm, including about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 105 nm, about 110 nm, about 120 nm, about 125 nm, about 130 nm, about 135 nm, about 140 nm, about 145 nm, and about 150 nm. In one or more embodiments, the semiconductor layers 104 have a thickness in the range of from about 50 to about 100 nm.

With reference to FIG. 4B, a mask layer 108 is formed on a top surface of the memory stack 112. The mask layer 108 may comprise any suitable hardmask material known to the skilled artisan. In one or more embodiments, the mask layer 108 comprises, consists essentially of, or consists of silicon oxide (SiOₓ) or carbon (C). In one or more embodiments, the mask layer 108 may have any suitable thickness. In some embodiments, the mask layer 108 has a thickness in a range of from 50 nm to 5000 nm.

Referring to FIG. 1 and FIG. 4C, at operation 14, the array region 100 is patterned to form an opening 114 that extends from a top surface of the memory stack 112 to a top surface of the insulating layer 102. In some embodiments, patterning the opening 114 comprises etching through the memory stack 112. In one or more embodiments, the insulating layer 102 serves as an etch stop. Referring to FIG. 4C, the opening 114 has sidewalls that extend through the memory stack 112 exposing surfaces of the sacrificial layers 106 and the semiconductor layers 104.

In one or more embodiments, the opening 114 has a depth in a range of from 0.5 nm to about 500 nm, including in a range of from about 5 nm to about 400 nm, or in a range a of from about 10 nm to about 300 nm, or in a range of from about 20 nm to about 200 nm.

The sacrificial layers 106 and the semiconductor layers 104 have surfaces exposed as sidewalls of the opening 114. The bottom of the opening 114 can be formed at any point within the thickness of the semiconductor layer 104. In some embodiments, the opening 114 extends a thickness into the semiconductor layer 104 in the range of from about 10% to about 90%, or in the range of from about 20% to about 80%, or in the range of from about 30% to about 70%, or in the range of from about 40% to about 60% of the thickness of the semiconductor layer 104. In some embodiments, the opening 114 extends a distance into the semiconductor layer 104 by greater than or equal to 10%, 20%, 30%, 40%, 50%, 60%, 70% or 80% of the thickness of the semiconductor layer 104.

Referring to FIG. 1 and FIGS. 4D to 4M, at operation 16, a cell transistor is formed. With reference to FIG. 4D, the sacrificial layers 106 are selectively removed or recessed to form a recess opening 116 adjacent to the semiconductor layers 104. The sacrificial layers 106 may be removed or recessed by one or more selective etching process including any suitable dry etching processing, any suitable wet etching processing, or other suitable etching techniques. For example, a dry etching process may implement an oxygen-containing gas, a fluorine-containing gas (e.g., CF₄, SF₆, CH₂F₂, CHF₃, and/or C₂F₆), a chlorine-containing (e.g., Cl₂, CHCl₃, CCl₄, and/or BCl₃), a bromine-containing gas (e.g., HBr and/or CHBr₃), an iodine-containing gas, other suitable gases and/or plasma, and/or combinations thereof. In one or more embodiments, the wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant(s).

Referring to FIG. 4E, in one or more embodiments, the semiconductor layers 104 are trimmed or thinned to increase the width of the opening 116. The semiconductor layers 104 may be trimmed by any suitable process known to the skilled artisan. In one or more embodiments, the semiconductor layers 104 may be trimmed by one or more etching process including any suitable dry etching processing, any suitable wet etching processing, or other suitable etching techniques.

With reference to FIG. 4F, in one or more embodiments, an insulating layer 120 is conformally deposited in the opening 114 through the memory stack 112. As illustrated in FIG. 4F, the insulating layer 120 forms on the exposed surfaces of the mask layer 108, the semiconductor layers 104, and on the sacrificial layers 106. In one or more embodiments, the insulating layer 120 forms on the bottom of the opening 114.

In one or more embodiments, deposition of the insulating layer 120 may be substantially conformal. As used herein, a layer which is “substantially conformal” refers to a layer where the thickness is about the same throughout (e.g., on the top, middle and bottom of sidewalls, and on the bottom of the feature 150). A layer which is substantially conformal varies in thickness by less than or equal to about 10%, 9%, 8%, 7%, 6%, 5%, 4%, 3%, 2%, 1%, or 0.5%.

In one or more embodiments, the insulating layer 120 may be any suitable dielectric material known to the skilled artisan. As used herein, the term “dielectric material” refers to a layer of material that is an electrical insulator that can be polarized in an electric field. In one or more embodiments, the insulating layer 120 comprises one or more of silicon oxide (SiOₓ), silicon nitride (SiN), silicon carbonitride (SiCN), silicon oxynitride (SiON), silicon oxycarbonitride (SiOCN), silicon boride (SiB), and silicon boron nitride (SiBN). In specific embodiments, the insulating layer 120 comprises silicon nitride (SiN).

In one or more embodiments, the conformal insulating layer 120 may comprise any suitable thickness. In some embodiments, the conformal insulating layer 120 has a thickness in a range of from greater than 0 nm to 100 nm, or in a range of from greater than 0 nm to 75 nm, or in a range of from greater than 0 nm to 50 nm, or in a range of from 1 nm to 100 nm, or in a range of from 1 nm to 50 nm, or in a range of from 5 nm to 100 nm, or in a range of from 5 nm to 50 nm, or in a range of from 5 nm to 30 nm.

The conformal insulating layer 120 may be deposited by any suitable technique known to the skilled artisan. In one or more embodiments, the conformal insulating layer 120 may be deposited by one or more of ALD, CVD, and PVD.

Referring to FIG. 4G, in one or more embodiments, the opening 118 is filled with an oxide material 122. The oxide material 122 may be deposited by any suitable technique, including, but not limited to, ALD, CVD, and PVD. In one or more embodiments, the oxide material 122 comprises any suitable oxide known to the skilled artisan. In some embodiments, the oxide material 122 comprises silicon oxide (SiOₓ).

With references to FIG. 4H, in one or more embodiments, the oxide material 122 and the insulating layer 120 is removed or etched from the sidewalls of the opening 114 to expose surfaces 126 of the semiconductor layers 104 and surfaces 128 of the mask layer 108.

Referring to FIG. 4I, in one or more embodiments, the insulating layer 120 is partially removed exposing a top and bottom surface of the oxide material 122 and forming an opening 130 between the exposed oxide material 122 and the semiconductor layers 104. It should be noted that that insulating layer 120 remains on the sacrificial layers 106.

The insulating layer 120 may be removed by any suitable technique known to the skill artisan. In one or more embodiments, the insulating layer 120 may be removed by one or more etching process including any suitable dry etching processing, any suitable wet etching processing, or other suitable etching techniques. In one or more embodiments, the insulating layer 120 may be removed using a solution of hot phosphorus.

With reference to FIG. 4J, in one or more embodiments, a gate oxide layer 132 is conformally formed on the surface of the exposed semiconductor layers 104. The gate oxide layer 132 may comprise any suitable material known to the skilled artisan. The gate oxide layer 132 can be deposited using one or more deposition techniques known to the skilled artisan. In one or more embodiments, the gate oxide layer 132 is deposited using one of deposition techniques, such as, but not limited to, ALD, CVD, PVD, MBE, MOCVD, spin-on, or other deposition techniques known to the skilled artisan. The illustrated embodiment shows the gate oxide layer 132 as a conformal layer with a uniform shape. However, the skilled artisan will recognize that this is merely for illustrative purposes and that the gate oxide layer 132 can form in an isotropic manner so that the gate oxide layer 132 has a rounded appearance. In some embodiments, the gate oxide layer 132 is selectively deposited as a conformal layer on the surface of the insulating layer 120. In some embodiments, the gate oxide layer 132 is formed by oxidation of the semiconductor surface.

In one or more embodiments, the gate oxide layer 132 comprises a silicon oxide (SiOₓ). While the term “silicon oxide” may be used to describe the gate oxide layer 132, the skilled artisan will recognize that the disclosure is not restricted to a particular stoichiometry. For example, the terms “silicon oxide” and “silicon dioxide” may both be used to describe a material having silicon and oxygen atoms in any suitable stoichiometric ratio. The same is true for the other materials listed in this disclosure, e.g., silicon nitride, silicon oxynitride, tungsten oxide, zirconium oxide, aluminum oxide, hafnium oxide, and the like.

The gate oxide layer 132 may comprise any suitable thickness. In some embodiments, the gate oxide layer 132 has a thickness in a range of from greater than 0 nm to 20 nm. In specific embodiments, the gate oxide layer 132 has a thickness in a range of from greater than 0 nm to about 10 nm, including about 0.5 nm, about 1 nm, about 1.5 nm, about 2 nm, about 2.5 nm, about 3 nm, about 3.5 nm, about 4 nm, about 4.5 nm, about 5 nm, about 5.5 nm, about 6 nm, about 6.5 nm, about 7 nm, about 7.5 nm, about 8 nm, about 8.5 nm, about 9 nm, about 9.5 nm, or about 10 nm.

Referring to FIG. 4K, in one or more embodiments, the word line 134 is then formed on the gate oxide layer 132. With reference to FIG. 4K′, which is an enlarged view of the section 4K′ in FIG. 4K, the word line 134 comprises one or more of a barrier layer 134a and a word line metal 134b. The barrier layer 134a may comprise any suitable barrier layer known to the skilled artisan. In one or more embodiments, the barrier layer 134a comprises one or more of titanium nitride (TiN), tantalum nitride (TaN), or the like. In one or more embodiments, the word line metal 134b comprises a bulk metal comprising one or more of copper (Cu), cobalt (Co), tungsten (W), aluminum (Al), ruthenium (Ru), iridium (Ir), molybdenum (Mo), platinum (Pt), tantalum (Ta), titanium (Ti), or rhodium (Rh). In one or more embodiments, the word line metal 134b comprises tungsten (W). In other embodiments, the word line metal 134b comprises ruthenium (Ru).

Referring to FIG. 4L, a portion of the word line 134 is recessed to form a recessed region 136. The word line 134 may be recessed by any suitable technique known to the skilled artisan. In one or more embodiments, the recess region 136 has a size in a range of from greater than 0 nm to 15 nm, or in a range of from 1 nm to 10 nm, including about 1 nm, about 1.5 nm, about 2 nm, about 2.5 nm, about 3 nm, about 3.5 nm, about 4 nm, about 4.5 nm, about 5 nm, about 5.5 nm, about 6 nm, about 6.5 nm, about 7 nm, about 7.5 nm, about 8 nm, about 8.5 nm, about 9 nm, about 9.5 nm, or about 10 nm.

With reference to FIG. 4M, in one or more embodiments, the opening 114 that extends through the memory stack 112 is filled with a dielectric material 138. The dielectric material 138 may comprise any suitable material known to the skilled artisan. In one or more embodiments, the dielectric material 138 comprises silicon oxide (SiOₓ).

With reference to FIG. 1 and FIG. 4N, at operation 18, the array region 100 is slit patterned to form slit pattern openings 140 that extend from a top surface of the memory stack 112 to the substrate 101.

Referring to FIG. 1 and FIGS. 4O to 4Z′, at operation 20, the cell capacitors are formed. With reference to FIG. 4O, the sacrificial layers 106 (i.e., silicon germanium (SiGe)) are selectively removed through slit patterning opening 140 to form an opening region 142 between the semiconductor layers 104. The sacrificial layers 106 may be removed or recessed by one or more selective etching process including any suitable dry etching processing, any suitable wet etching processing, or other suitable etching techniques. For example, a dry etching process may implement an oxygen-containing gas, a fluorine-containing gas (e.g., CF₄, SF₆, CH₂F₂, CHF₃, and/or C₂F₆), a chlorine-containing (e.g., Cl₂, CHCl₃, CCl₄, and/or BCl₃), a bromine-containing gas (e.g., HBr and/or CHBr₃), an iodine-containing gas, other suitable gases and/or plasma, and/or combinations thereof. In one or more embodiments, the wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant(s).

Referring to FIG. 4P, in one or more embodiments, the semiconductor layers 104 are trimmed or thinned to increase the width of the opening 142. The semiconductor layers 104 may be trimmed by any suitable process known to the skilled artisan. In one or more embodiments, the semiconductor layers 104 may be trimmed by one or more etching process including any suitable dry etching processing, any suitable wet etching processing, or other suitable etching techniques.

Referring to FIG. 4Q, in one or more embodiments, an insulating layer 146 is conformally deposited in the opening 142 through the slit pattern opening 140. As illustrated in FIG. 4Q, the insulating layer 146 forms on the exposed surfaces of the mask layer 108 and the semiconductor layers 104. In one or more embodiments, the insulating layer 146 forms on the bottom of the slit pattern opening 140.

In one or more embodiments, deposition of the insulating layer 146 may be substantially conformal. As used herein, a layer which is “substantially conformal” refers to a layer where the thickness is about the same throughout (e.g., on the top, middle and bottom of sidewalls, and on the bottom of the feature 150). A layer which is substantially conformal varies in thickness by less than or equal to about 10%, 9%, 8%, 7%, 6%, 5%, 4%, 3%, 2%, 1%, or 0.5%.

In one or more embodiments, the insulating layer 146 may be any suitable dielectric material known to the skilled artisan. As used herein, the term “dielectric material” refers to a layer of material that is an electrical insulator that can be polarized in an electric field. In one or more embodiments, the insulating layer 146 comprises one or more of silicon oxide (SiOₓ), silicon nitride (SiN), silicon carbonitride (SiCN), silicon oxynitride (SiON), silicon oxycarbonitride (SiOCN), silicon boride (SiB), and silicon boron nitride (SiBN). In specific embodiments, the insulating layer 146 comprises silicon nitride (SiN).

In one or more embodiments, the conformal insulating layer 146 may comprise any suitable thickness. In some embodiments, the conformal insulating layer 146 has a thickness in a range of from greater than 0 nm to 100 nm, or in a range of from greater than 0 nm to 75 nm, or in a range of from greater than 0 nm to 50 nm, or in a range of from 1 nm to 100 nm, or in a range of from 1 nm to 50 nm, or in a range of from 5 nm to 100 nm, or in a range of from 5 nm to 50 nm, or in a range of from 5 nm to 30 nm.

The conformal insulating layer 146 may be deposited by any suitable technique known to the skilled artisan. In one or more embodiments, the conformal insulating layer 146 may be deposited by one or more of ALD, CVD, and PVD.

Referring to FIG. 4R, in one or more embodiments, the opening 142 is filled with an oxide material 148. The oxide material 148 may be deposited by any suitable technique, including, but not limited to, ALD, CVD, and PVD. In one or more embodiments, the oxide material 148 comprises any suitable oxide known to the skilled artisan. In some embodiments, the oxide material 148 comprises silicon oxide (SiOₓ). In one or more embodiments, the oxide material 148 is removed from the sidewall surfaces of the slit pattern opening 140.

With reference to FIG. 4S, in one or more embodiments, the semiconductor layers 104 are removed or exhumed through the slit pattern opening 140 to form an opening 150 adjacent to the insulating layer 146. The semiconductor layers 104 may be removed by any suitable technique. In one or more embodiments, the semiconductor layers 104 may be removed using tetramethylammonium hydroxide (TMAH).

Referring to FIG. 4T, in one or more embodiments the source/drain 152 is formed adjacent the exposed surface of the semiconductor layers 104 in the opening 150. The source/drain 152 may comprise any suitable material. In one or more embodiments, the source/drain 152 is doped using gas phase doping, e.g., with PH3 as a doping gas at a temperature in a range of from 400° C. to 1000° C.

Referring to FIG. 4U, in one or more embodiments, the bottom electrode 154 is formed on the insulating layer 146. The bottom electrode 152 may comprise any suitable material known to the skilled artisan. In some embodiments, the bottom electrode 152 comprises titanium nitride (TiN).

With reference to FIG. 4V, in one or more embodiments, a high-K dielectric layer 156 is formed on the bottom electrode 154. The high-K dielectric layer 156 may comprise any suitable material known to the skilled artisan. High-K dielectric materials may provide greater channel mobility over silicon oxide at similar thicknesses. In one embodiments, high-K dielectric layer 156 comprises a metal selected from one or more of hafnium (Hf), zirconium (Zr), silicon (Si), lanthanum (La), aluminum (Al), titanium (Ti), and strontium (Sr). In some embodiments, high-K dielectric layer 156 comprises one or more of hafnium oxide (HfOx), zirconium oxide (ZrOx), silicon oxide (SiOx), lanthanum oxide (LaOx), aluminum oxide (AIOx), titanium oxide (TiOx), strontium oxide (SrOx), hafnium zirconium oxide (HfZrO), and the like.

Referring to FIG. 4W, in one or more embodiments, a top electrode 158 is formed on the high-K dielectric layer 156 to form the capacitors 159. The top electrode 158 may comprise any suitable material known to the skilled artisan. In some embodiments, the top electrode 158 comprises titanium nitride (TiN).

With reference to FIG. 4X, the bit line opening 160 is patterned. The bit line opening 160 may be patterned by any suitable means known to the skilled artisan.

With reference to FIG. 4Y, a source/drain 162 is formed through the bit line opening 160 on the surface of the semiconductor layers 104. The source/drain 162 may comprise any suitable material. In one or more embodiments, the source/drain 162 is doped using gas phase doping, e.g., with PH₃ as a doping gas at a temperature in a range of from 400° C. to 1000° C.

Referring to FIGS. 4Z and 4Z′, in one or more embodiments, the bit line opening 160 is filled and the bit line 164 is formed. Accordingly, the cell capacitor 170 and the cell transistor 172 are formed. With reference to FIG. 4Z′, which is an enlarged view of the section 170 in FIG. 4Z, the bit line 164 comprises one or more of a barrier layer 164a and a bit line metal 164b. The barrier layer 164a may comprise any suitable barrier layer known to the skilled artisan. In one or more embodiments, the barrier layer 164a comprises one or more of titanium nitride (TiN), tantalum nitride (TaN), or the like. In one or more embodiments, the bit line metal 164b comprises a bulk metal comprising one or more of copper (Cu), cobalt (Co), tungsten (W), aluminum (Al), ruthenium (Ru), iridium (Ir), molybdenum (Mo), platinum (Pt), tantalum (Ta), titanium (Ti), or rhodium (Rh). In one or more embodiments, the bit line metal 164b comprises tungsten (W). In other embodiments, the bit line metal 164b comprises ruthenium (Ru).

The optional bit line barrier layer 164a can be made of any suitable material deposited by any suitable technique known to the skilled artisan. In one or more embodiments, the bit line barrier layer 164a is deposited on the source/drain region at the inner end of the active material. The bit line barrier layer 164a can be any suitable material including, but not limited to, titanium nitride (TiN) or tantalum nitride (TaN). In some embodiments, the optional bit line barrier layer 164a comprises or consists essentially of titanium nitride (TiN). As used in this manner, the term “consists essentially of” means that the composition of the film is greater than or equal to about 95%, 98%, 99% or 99.5% of the stated species. In some embodiments, the optional bit line barrier layer 164a comprises or consists essentially of tantalum nitride (TaN). In some embodiments, the bit line barrier layer 164a is a conformal layer. In some embodiments, the bit line barrier layer 164a is deposited by atomic layer deposition.

In some embodiments, the bit line 164 comprises a bit line metal 164b. The bit line metal 164b may comprise any suitable metal known to the skilled artisan. In one or more embodiments, the bit line metal 164b comprises or consists essentially of one or more of tungsten silicide (WSi), tungsten nitride (WN), or tungsten (W). The bit line metal 164b can be deposited by any suitable technique known to the skilled artisan and can be any suitable material. In one or more embodiments, forming the bit line 164 further comprises forming a bit line metal seed layer (not shown) prior to depositing the bit line metal 164b.

With reference to FIG. 1 and FIGS. 5A to 5M, which are cross-sectional views taken along line C-D of FIG. 4 to illustrate the word line contact region 200, at operation 22, word line contacts are formed on the front side of the device. As illustrated in FIG. 5A, which is a cross-sectional view of the word line contact region 200, the memory stack 112 is slit patterned to form a slit pattern opening 202, which extends from the top surface of the memory stack to the insulating layer 102. The slit pattern opening 202 may have any suitable dimensions. In some embodiments, the slit pattern opening as a critical dimension in a range of from about 1 nm to about 1000 nm, or in a range of from about 5 nm to about 500 nm, or in a range of from about 10 nm to about 400 nm, or in a range of from about 15 nm to about 300 nm, or in a range of from about 20 nm to about 200 nm.

With reference to FIG. 5B, the sacrificial layers 106 (i.e., silicon germanium (SiGe)) are selectively removed through slit patterning opening 202 to form an opening region 204 between the semiconductor layers 104. The sacrificial layers 106 may be removed or recessed by one or more selective etching process including any suitable dry etching processing, any suitable wet etching processing, or other suitable etching techniques. For example, a dry etching process may implement an oxygen-containing gas, a fluorine-containing gas (e.g., CF₄, SF₆, CH₂F₂, CHF₃, and/or C₂F₆), a chlorine-containing (e.g., Cl₂, CHCl₃, CCl₄, and/or BCl₃), a bromine-containing gas (e.g., HBr and/or CHBr₃), an iodine-containing gas, other suitable gases and/or plasma, and/or combinations thereof. In one or more embodiments, the wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant(s).

Referring to FIG. 5C, in one or more embodiments, the semiconductor layers 104 are trimmed or thinned to increase the width of the opening 204 to form a wide opening 206. The semiconductor layers 104 may be trimmed by any suitable process known to the skilled artisan. In one or more embodiments, the semiconductor layers 104 may be trimmed by one or more etching process including any suitable dry etching processing, any suitable wet etching processing, or other suitable etching techniques.

Referring to FIG. 5D, in one or more embodiments, an insulating layer 208 is conformally deposited in the opening 206 through the slit pattern opening 202. As illustrated in FIG. 4D, the insulating layer 208 forms on the exposed surfaces of the mask layer 108 and the semiconductor layers 104. In one or more embodiments, the insulating layer 208 forms on the bottom of the slit pattern opening 202.

In one or more embodiments, the insulating layer 208 may be any suitable dielectric material known to the skilled artisan. As used herein, the term “dielectric material” refers to a layer of material that is an electrical insulator that can be polarized in an electric field. In one or more embodiments, the insulating layer 146 comprises one or more of silicon oxide (SiOx), silicon nitride (SiN), silicon carbonitride (SiCN), silicon oxynitride (SiON), silicon oxycarbonitride (SiOCN), silicon boride (SiB), and silicon boron nitride (SiBN). In specific embodiments, the insulating layer 208 comprises silicon nitride (SiN).

The insulating layer 208 may be deposited by any suitable technique known to the skilled artisan. In one or more embodiments, the insulating layer 208 may be deposited by one or more of ALD, CVD, and PVD.

Referring to FIG. 5E, in one or more embodiments, the insulating layer 208 is removed from the sidewall surface of the slit pattern opening 202, exposing the sidewall surfaces of the semiconductor layers 104. In one or more embodiments, the insulating layer 208 is also removed from the top surface of the mask layer 108 and from the bottom surface of the slit pattern opening 202. In one or more embodiments, the insulating layer 208 may be removed by one or more etching process including any suitable dry etching processing, any suitable wet etching processing, or other suitable etching techniques.

In one or more embodiments, as illustrated in FIG. 5F, the semiconductor layers 104 are removed to form an opening 210 adjacent to the insulating layer 208. The semiconductor layers 104 may be removed by any suitable process known to the skilled artisan. In one or more embodiments, the semiconductor layers 104 may be removed by one or more etching process including any suitable dry etching processing, any suitable wet etching processing, or other suitable etching techniques.

Referring to FIG. 5G, in one or more embodiments, the opening 210 is filled to form a conductor layer 212. In one or more embodiments, the conductor layer 212 comprises a metal. In some embodiments, the metal of the conductor layer 212 includes one or more copper (Cu), cobalt (Co), tungsten (W), aluminum (Al), ruthenium (Ru), iridium (Ir), molybdenum (Mo), platinum (Pt), tantalum (Ta), titanium (Ti), rhodium (Rh). In one or more embodiments, the conductor layer 212 may comprise a nitride. In some embodiments, the nitride includes one or more of copper nitride (CuN), cobalt nitride (CON), tungsten nitride (WN), aluminum nitride (AlN), ruthenium nitride (RUN), iridium nitride (IrN), molybdenum nitride (MoN), platinum nitride (PtN), tantalum nitride (TaN), titanium nitride (TiN), rhodium nitride (RhN), and the like. In other embodiments, the conductor layer 212 may comprise a semiconductor material including, but not limited to, one or more of silicon (Si), silicon germanium (SiGe), or germanium (Ge).

With reference to FIG. 5H, in one or more embodiments, the slit pattern opening 202 is filled with an oxide material 214. The oxide material 214 may be deposited by any suitable technique, including, but not limited to, ALD, CVD, and PVD. In one or more embodiments, the oxide material 214 comprises any suitable oxide known to the skilled artisan. In some embodiments, the oxide material 214 comprises silicon oxide (SiOx).

Referring to FIG. 5I, in one or more embodiments, the device is patterned to form a first word line contact opening 216. In some embodiments, the first word line contact opening extends from a top surface of the mask layer 108 through an insulating layer 208 and through a conductor layer 212. The first word line contact opening 216 may be patterned by any suitable means. The first word line contact opening 216 may have any suitable aspect ratio (ratio of the depth of the feature to the width of the feature). In one or more embodiments, the first word line contact opening 216 described herein has a critical dimension in a range of from greater than 0 nm to about 500 nm, or in a range of from about 10 nm to about 500 nm, on in a range of from about 25 nm to about 500 nm, or in a range of from about 50 nm to about 300 nm. In one or more embodiments, the first word line contact opening 216 has a depth or height in a range of from greater than 0 μm to 20 μm, or in a range of from 0.1 μm to 10 μm.

Referring to FIG. 5J, in one or more embodiments, the device is patterned to form a second word line contact opening 218. In some embodiments, the second word line contact opening extends from the top surface of the mask layer 108 through an insulating layer 208 and through two word lines 212. The second word line contact opening 218 may be patterned by any suitable means. The second word line contact opening 218 may have any suitable aspect ratio (ratio of the depth of the feature to the width of the feature). In one or more embodiments, the second word line contact opening 218 described herein has a critical dimension width in a range of from greater than 0 nm to about 500 nm, or in a range of from about 10 nm to about 500 nm, on in a range of from about 25 nm to about 500 nm, or in a range of from about 50 nm to about 300 nm. In one or more embodiments, the second word line contact opening 218 has a depth or height in a range of from greater than 0 μm to 20 μm, or in a range of from 0.1 μm to 10 μm. In one or more embodiments, the second word line contact opening 218 has a depth or a height that is greater than the depth or height of the first word line contact opening 216.

With reference to FIG. 5K, in one or more embodiments, a liner layer 220 is conformally deposited in the first word line contact opening 216 and in the second word line contact opening 218. In one or more embodiments, deposition of the liner layer 220 may be substantially conformal. As used herein, a layer which is “substantially conformal” refers to a layer where the thickness is about the same throughout (e.g., on the top, middle and bottom of sidewalls, and on the bottom of the feature 150). A layer which is substantially conformal varies in thickness by less than or equal to about 10%, 9%, 8%, 7%, 6%, 5%, 4%, 3%, 2%, 1%, or 0.5%.

In one or more embodiments, the liner layer 220 may be any suitable dielectric material known to the skilled artisan. In one or more embodiments, the liner layer 220 comprises silicon oxide (SiOx).

As illustrated in FIG. 5L, in one or more embodiments, the liner layer 220 is removed from the bottom of the first word line contact opening 216 and from the bottom surface of the second word line contact opening 218. The liner layer 220 may be removed by any suitable etch process described herein.

Referring to FIG. 5M, in one or more embodiments, the first word line contact opening 216 and the second word line contact opening 218 are filled with a conductive material 222. The conductive material 222 may comprise any suitable material that is conductive. In one or more embodiments, the conductive material 222 comprises one or more of titanium nitride (TiN), tantalum nitride (TaN), copper (Cu), cobalt (Co), tungsten (W), aluminum (Al), ruthenium (Ru), iridium (Ir), molybdenum (Mo), platinum (Pt), tantalum (Ta), titanium (Ti), rhodium (Rh), or the like.

With reference to FIG. 1 and FIG. 5N, at operation 24, the frontside metallization 224 is formed. In one or more embodiments, the frontside metallization 224, may comprise any suitable material. In some embodiments, the frontside metallization 224 comprises one or more of titanium nitride (TiN), tantalum nitride (TaN), copper (Cu), cobalt (Co), tungsten (W), aluminum (Al), ruthenium (Ru), iridium (Ir), molybdenum (Mo), platinum (Pt), tantalum (Ta), titanium (Ti), rhodium (Rh), or the like.

With reference to FIG. 1 and, as illustrated in FIG. 6A, at operation 26, the array wafer 502 having the array region 100 and word line contact region 200 thereon, is bonded to the peri wafer 504 to form the device 600. The bonding comprises any suitable bonding process known to the skilled artisan. In one or more embodiments, the peri wafer 504 is electrically connected with the word line contacts by a through hole via (THV) 501.

With reference to FIG. 1 and, as illustrated in FIG. 6B, at operation 28, the backside of the array wafer is subjected to grinding such that the substrate 101 of the array region 100 and the word line contact region 200 is removed. The grinding may be any suitable grinding process known to the skilled artisan.

With reference to FIG. 1 and, as illustrated in FIG. 6C, at operation 30, word line contacts 506,508 are formed on the backside of the device 600. As recognized by one of skill in the art, the word line contacts 504 are formed according to the methods described and illustrated with respect to FIGS. 5A to 5N. In one or more embodiments, the first word line contact opening 506 described herein has a critical dimension width in a range of from greater than 0 nm to about 500 nm, or in a range of from about 10 nm to about 500 nm, on in a range of from about 25 nm to about 500 nm, or in a range of from about 50 nm to about 300 nm. In one or more embodiments, the first word line contact opening 506 has a depth or height in a range of from greater than 0 μm to 20 μm, or in a range of from 0.1 μm to 10 μm. In one or more embodiments, the second word line contact opening 508 described herein has a critical dimension width in a range of from greater than 0 nm to about 500 nm, or in a range of from about 10 nm to about 500 nm, on in a range of from about 25 nm to about 500 nm, or in a range of from about 50 nm to about 300 nm. In one or more embodiments, the second word line contact opening 508 has a depth or height in a range of from greater than 0 μm to 20 μm, or in a range of from 0.1 μm to 10 μm. In one or more embodiments, the second word line contact opening 508 has a depth or a height that is greater than the depth or height of the first word line contact opening 506.

With reference to FIG. 1 and, as illustrated in FIG. 6D, at operation 32, the backside of the device 600 is patterned, and, at operation 34, the backside metallization 510 is formed. In one or more embodiments, the backside metallization 510, may comprise any suitable material. In some embodiments, the backside metallization 510 comprises one or more of titanium nitride (TiN), tantalum nitride (TaN), copper (Cu), cobalt (Co), tungsten (W), aluminum (Al), ruthenium (Ru), iridium (Ir), molybdenum (Mo), platinum (Pt), tantalum (Ta), titanium (Ti), rhodium (Rh), or the like.

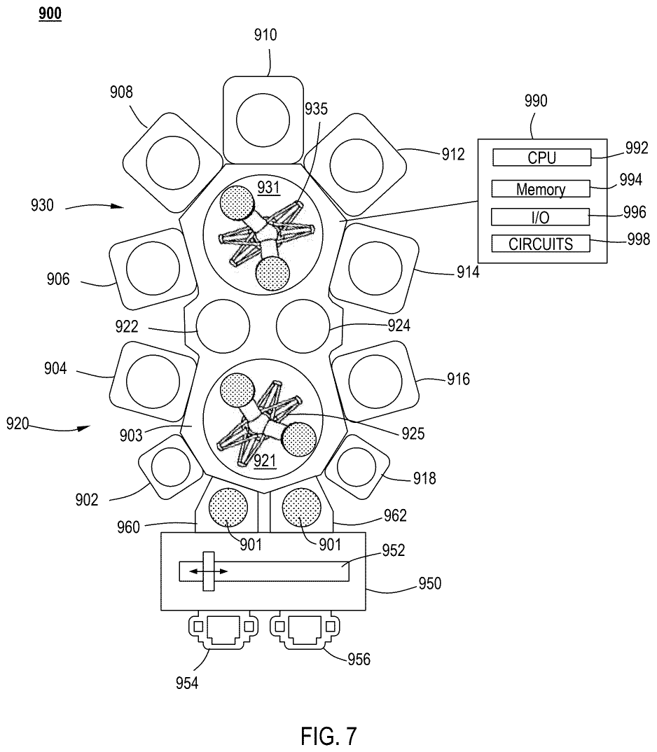

Additional embodiments of the disclosure are directed to processing tools 900 for the formation of the memory devices and methods described, as shown in FIG. 7. The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber, annealing chamber, etching chamber, a selective etching chamber, and the like. The particular arrangement of process chambers and components can be varied depending on the cluster tool and should not be taken as limiting the scope of the disclosure.

In the embodiment shown in FIG. 7, a factory interface 950 is connected to the front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit (CPU), memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware such as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A memory device comprising:
a plurality of stacked word lines coupled to a plurality of stacked memory cells, the plurality of stacked word lines comprising a first word line and a second word line;
a first word line contact in contact with the first word line and extending in a first direction from the first word line; and
a second word line contact in contact with the second word line and extending in a second direction from the second word line, wherein the second direction is opposite to the first direction.

2. The memory device of claim 1, wherein the plurality of stacked word lines comprises a third word line and a fourth word line, and the memory device comprises:
a third word line contact contacting the third word line and extending in the first direction from the third word line; and
a fourth word line contact contacting the fourth word line and extending in the second direction from the fourth word line.

3. The memory device of claim 2, wherein first word line contact has a height that is greater than a height of the third word line contact, and the second word line contact has a height that is greater than a height of the fourth word line contact.

4. A memory device comprising:
a memory stack comprising a plurality of conductor layers and semiconductor layers and a corresponding plurality of dielectric layers alternatingly arranged in a plurality of stacked pairs, the memory stack having a first direction and a second direction;
at least two first contact regions extending in the first direction; and
at least two second contact regions extending in the second direction.

5. The memory device of claim 4, wherein the plurality of conductor layers comprises a one or more of copper (Cu), cobalt (Co), tungsten (W), aluminum (Al), ruthenium (Ru), iridium (Ir), molybdenum (Mo), platinum (Pt), tantalum (Ta), titanium (Ti), rhodium (Rh), or nitrides thereof.

6. The memory device of claim 4, wherein the plurality of semiconductor layers comprises one or more of silicon (Si), silicon germanium (SiGe), or germanium (Ge) and wherein the plurality of dielectric layers comprises one or more of silicon oxide (SiOx), silicon nitride (SIN), silicon carbonitride (SiCN), silicon oxynitride (SiON), silicon oxycarbonitride (SiOCN), silicon boride (SiB), and silicon boron nitride (SiBN).

7. The memory device of claim 4, wherein the first contact regions and the second contact regions independently comprise one or more of doped silicon, titanium nitride (TiN), tantalum nitride (TaN), copper (Cu), cobalt (Co), tungsten (W), aluminum (Al), ruthenium (Ru), iridium (Ir), molybdenum (Mo), platinum (Pt), tantalum (Ta), titanium (Ti), or rhodium (Rh).

8. A memory device comprising:
an array region on a substrate, the array region including a cell transistor and a cell capacitor; and
a contact region having a first direction and a second direction adjacent the array region on the substrate, the contact region comprising:
a plurality of conductor layers and semiconductor layers and a corresponding plurality of dielectric layers alternatingly arranged in a plurality of stacked pairs,
at least two first contact regions extending in the first direction, and
at least two second contact regions extending in the second direction.

9. The memory device of claim 8, wherein the plurality of conductor layers comprises a one or more of copper (Cu), cobalt (Co), tungsten (W), aluminum (Al), ruthenium (Ru), iridium (Ir), molybdenum (Mo), platinum (Pt), tantalum (Ta), titanium (Ti), rhodium (Rh), or nitrides thereof.

10. The memory device of claim 8, wherein the plurality of semiconductor layers comprises one or more of silicon (Si), silicon germanium (SiGe), or germanium (Ge) and wherein the plurality of dielectric layers comprises one or more of silicon oxide (SiOx), silicon nitride (SiN), silicon carbonitride (SiCN), silicon oxynitride (SiON), silicon oxycarbonitride (SiOCN), silicon boride (SiB), and silicon boron nitride (SiBN).

11. The memory device of claim 8, wherein the first contact regions and the second contact regions independently comprises one or more of doped silicon, titanium nitride (TiN), tantalum nitride (TaN), copper (Cu), cobalt (Co), tungsten (W), aluminum (Al), ruthenium (Ru), iridium (Ir), molybdenum (Mo), platinum (Pt), tantalum (Ta), titanium (Ti), or rhodium (Rh).

12. The memory device of claim 8, further comprising a peri substrate electrically connected with the first contact regions and the second contact regions by a through hole via.

13. The memory device of claim 8, wherein the memory device is a 3D DRAM device.

14. A method of manufacturing a memory device, the method comprising:
forming a memory stack on a substrate, the memory stack comprising a plurality of conductor layers and semiconductor layers and a corresponding plurality of dielectric layers alternatingly arranged in a plurality of stacked pairs, the memory stack having a first direction and a second direction;
patterning the memory stack in the first direction to form a plurality of first contact openings extending in the first direction;
patterning the memory stack in the second direction to form a plurality of second contact openings extending in the second direction; and
depositing a conductive material in each of the plurality of first contact openings and in the plurality of second contact openings to form a plurality of first contacts and a plurality of second contacts, the plurality of first contacts extending along the first direction and the plurality of second contacts extending along the second direction.

15. The method of claim 14, wherein the plurality of conductor layers comprise a one or more of copper (Cu), cobalt (Co), tungsten (W), aluminum (Al), ruthenium (Ru), iridium (Ir), molybdenum (Mo), platinum (Pt), tantalum (Ta), titanium (Ti), rhodium (Rh), or nitrides thereof.

16. The method of claim 14, wherein the plurality of semiconductor layers comprises one or more of silicon (Si), silicon germanium (SiGe), or germanium (Ge) and wherein the plurality of dielectric layers comprises one or more of silicon nitride (SiN), silicon carbonitride (SiCN), silicon oxynitride (SiON), silicon oxycarbonitride (SiOCN), silicon boride (SiB), and silicon boron nitride (SiBN).

17. The method of claim 14, wherein the plurality of first contacts and the plurality of second contacts independently comprises one or more of doped silicon, titanium nitride (TiN), tantalum nitride (TaN), copper (Cu), cobalt (Co), tungsten (W), aluminum (Al), ruthenium (Ru), iridium (Ir), molybdenum (Mo), platinum (Pt), tantalum (Ta), titanium (Ti), or rhodium (Rh).

18. The method of claim 14, further comprising forming a through hole via to electrically connect with the plurality of first contacts and the plurality of second contacts to a peri substrate.

19. The method of claim 14, wherein the memory device is a 3D DRAM device.

20. A non-transitory computer readable medium including instructions, that, when executed by a controller of a processing chamber, causes the processing chamber to perform operations of the method of claim 14.
